(19) United States
(12) Patent Application Publication
(10) Pub. No.: US 2026/0237448 A1
(43) Pub. Date: Aug. 13, 2026

(54) EFUSE BIT-CELL IN STACKING STRUCTURE

(71) Applicant: Taiwan Semiconductor Manufacturing Company, Ltd., Hsinchu (TW)

(72) Inventors: Meng-Sheng Chang, Hsinchu City (TW); Yao-Jen Yang, Hsinchu City (TW)

(73) Assignee: Taiwan Semiconductor Manufacturing Company, Ltd., Hsinchu (TW)

(21) Appl. No.: 19/209,032

(22) Filed: May 15, 2025

Related U.S. Application Data
(60) Provisional application No. 63/756,979, filed on Feb. 11, 2025.

(51) Int. Cl. G11C 17/16; G11C 17/18

(52) U.S. Cl. CPC G11C 17/16; G11C 17/18

(57) ABSTRACT

A memory device includes a plurality of memory cells, each of the plurality of memory cells comprising an access transistor, a control gate transistor, a resistive element, a read select transistor, and a write select transistor; word lines; control gate lines; bit lines; read select lines; and write select lines. For each of the plurality of memory cells, the access transistor, the control gate transistor, and the resistive element are connected to one another in series, a gate terminal of the access transistor and a gate terminal of the control gate transistor are connected to first and second source/drain terminals of the read select transistor, respectively, and the gate terminal of the control gate transistor and a corresponding one of the control gate lines are connected to first and second source/drain terminals of the write select transistor, respectively.

### CROSS-REFERENCE TO RELATED APPLICATION

This application claims the benefit of and priority to U.S. Provisional Application No. 63/756,979, filed Feb. 11, 2025, titled “eFuse Bit-Cell in Stacking Structure for Enhanced Leakage Tolerance,” which is incorporated herein by reference in its entirety.

### BACKGROUND

An eFuse bit-cell is a non-volatile memory element used for one-time programmable (OTP) storage in integrated circuits. The resistance of a fuse-like structure can be permanently altered during operation, allowing selective programming of stored data. eFuse bit-cells may be employed for device configuration, security key storage, or chip identification. eFuse technology can allow on-chip programming without requiring external memory components, contributing to secure and efficient customization of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit including a memory array, in accordance with some embodiments.

FIG. 2 illustrates an example schematic diagram of an eFuse cell in the memory array of FIG. 1, in accordance with some embodiments.

FIGS. 3A-B illustrate example schematic diagrams of the eFuse cell of FIG. 2 during operation, in accordance with some embodiments.

FIG. 4 illustrates an example schematic diagram of two eFuse cells in the memory array of FIG. 1, in accordance with some embodiments.

FIGS. 5A-5B illustrate example schematic diagrams of the memory array including eFuse cells of at least FIG. 2 during operation, in accordance with some embodiments.

FIG. 6 illustrates an example schematic diagram of an eFuse cell with p-channel metal-oxide-semiconductor (PMOS) switches in the memory array of FIG. 1, in accordance with some embodiments.

FIG. 7 illustrates an example schematic diagram of an eFuse cell with mix switches in the memory array of FIG. 1, in accordance with some embodiments.

FIG. 8 illustrates an example schematic diagram of eFuse cells coupled to switches in the memory array of FIG. 1, in accordance with some embodiments.

FIG. 9 illustrates an example schematic diagram of an eFuse cell with three transistors in the memory array of FIG. 1, in accordance with some embodiments.

FIG. 10 illustrates an example schematic diagram of an eFuse cell in the memory array of FIG. 1 including multiple access transistors and switches, in accordance with some embodiments.

FIG. 11 illustrates a flow chart of an example method for forming a memory device including eFuse bit-cells in stacking structure of FIGS. 1-10 to enhance leakage tolerance, in accordance with some embodiments.

FIG. 12 illustrates a flow chart of an example method for operating a memory device including eFuse bit-cells in stacking structure of FIGS. 1-10 to enhance leakage tolerance, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the field of semiconductor memory technology, eFuse and/or one-time programmable (OTP) memory programming can be utilized for various applications, such as in advanced node core-only high-voltage (HV) memory circuits. The eFuse or OTP can include, correspond to, or be implemented in one or more memory arrays. The memory arrays, such as e-Fuse or OTP, can be employed for storing data. The data stored in these memory arrays can be maintained or remain unchanged once written. The data stored in the memory arrays can be read subsequent to the writing procedure (or programming) of the memory arrays. In certain systems, access transistors may be stacked to potentially protect against over-voltage stress for reliability and longevity of memory cells. Further, the second word lines for these stacked access transistors, e.g., sometimes referred to as control gate transistors, may be asserted in the same manner as bit lines (BLs) to access specific bit cells. However, such an approach may involve the control gate transistors activating or being asserted to protect the stacked access transistors in unselected bit cells, thereby leading to higher leakage currents during read operations, for example. The activation of all control gate transistors in every read cycle is unnecessary and can increase leakage (e.g., current or electrical leakage), which may adversely affect or degrade the read margins or overall performance of the memory array.

In some cases, the potential leakage from activating the control gate transistors during the read cycle may be exacerbated in advanced node memory circuits where the capacitive loading of bit lines is relatively high. For instance, leakage of unselected bits (or cells) may compromise the read margins. In some cases, having a structure that combines control gate activation with bit line address decoding can lead to a relatively higher total bit line capacitive loading during the read operation, potentially contributing to the leakage. Hence, it may be desired to form or fabricate eFuse bit-cell in a stacking structure for enhanced leakage tolerance to reduce leakage and improve the reliability and performance of memory arrays.

The present disclosure provides various embodiments of a circuit including at least two additional metal-oxide-semiconductor (MOS) transistors to separate the program and read modes on the control gate controller. The present disclosure can involve modifying the two-transistor (2T) structure by adding at least one switch (e.g., utilizing the additional transistor(s) as switch(es)) in the bit cell to differentiate between program and read modes. The two additional transistors can be controlled independently to separate the read and write (or program) operations for individual bit cells. For example, the two additional transistors can include a write select transistor and a read select transistors. Depending on the mode, the write select transistor and the read select transistor can be activated/asserted/turned on or deactivated/deasserted/turned off, respective. Asserting or deasserting the write select transistor can connect or disconnect the control gate line (CG) to a gate terminal of a control gate transistor of the 2T structure, respectively. Asserting or deasserting the read select transistor can connect or disconnect the WL to the gate terminal of the control gate transistor, respectively.

For instance, in the program mode, the write select transistor can be activated and the read select transistor can be deactivated. In the read mode, the write select transistor can be deactivated and the read select transistor can be activated. The word line (WL), the bit line (BL), and the CG can be set to respective predefined voltages for at least the selected cells according to the mode. By implementing the additional transistor(s) (e.g., switch(es)), the program and read modes can be separated to ensure that the control gate transistors of unselected bit cells are not unnecessarily activated during read operations, thus minimizing or avoiding leakage through unselected cells and improving the read margins, without introducing stress (or changes) to the memory cells during the program mode. The features or functionalities of the present disclosure can be implemented in a memory array of any size, not limited to those discussed herein. As a non-limiting example herein, the systems and methods can include a memory circuit comprising a 64×64 memory array, where the off-state leakage current of unselected bits can be significantly reduced.

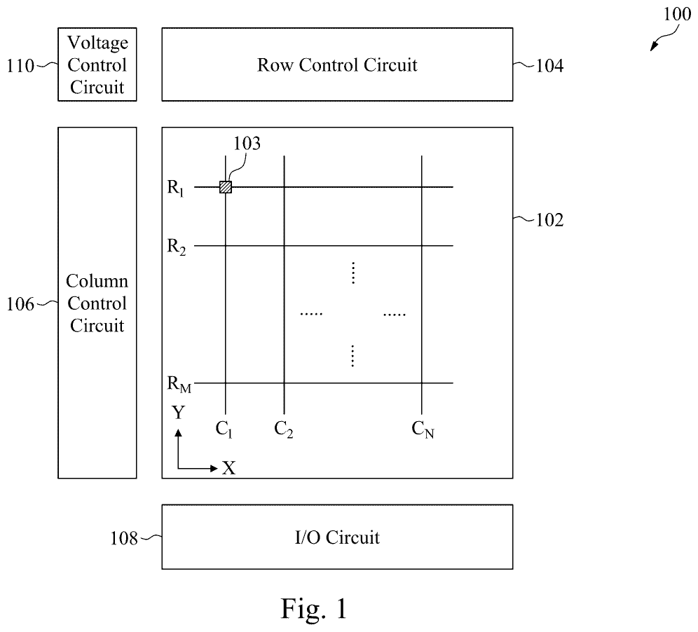

FIG. 1 illustrates a block diagram of an example circuit 100 including a voltage control circuit that can be configured to provide different voltages for operating a memory array, in accordance with various embodiments. For example, the memory circuit 100 can include a memory array 102, a row control circuit (e.g., a driver, decoder, and/or level shifter) 104, a column control circuit (e.g., a driver, decoder, and/or level shifter) 106, an input/output (I/O) circuit 108, and a voltage control circuit 110. Despite not being expressly shown in FIG. 1, all of the components of the memory circuit 100 may be operatively coupled to one another. Although, in the illustrated embodiment of FIG. 1, each component is shown as a separate block for the purpose of clear illustration, in some other embodiments, some or all of the components shown in FIG. 1 may be integrated together.

The memory array 102 is a hardware component that stores data. In various embodiments, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows and columns may include one or more conductive (e.g., metal) structures functioning as access lines, e.g., bit lines (BLs), word lines (WLs), and source/select lines (SLs). Each memory cell 103 is arranged in the intersection of a corresponding row and a corresponding column, and can be operated according to voltages or currents through the respective conductive structures of the column and row. For example, each of the rows may include one or more corresponding WLs, and each of the columns may include one or more corresponding BLs and one or more corresponding SLs. In this example, the row control circuit 104 can include at least a WL decoder and a WL level shifter and the column control circuit 106 can include at least a BL decoder and a BL level shifter.

The decoder can be configured to select one or more respective lines (e.g., WLs or BLs) based on an input address (e.g., n-bit address). For example, the WL decoder of the row control circuit 104 can be configured to receive and decode a first portion of an address signal and the BL decoder of the column control circuit 106 can be configured to receive and decode a second portion of the address signal. The WL decoder can select one or more of the WLs based on the first portion of the address signal, and the BL decoder can select one or more of the BLs based on the second portion of the address signal. The level shifter can be configured to adjust/shift or otherwise change respective voltages in at least one of the lines (e.g., WL voltage, BL voltage, CG voltage, read select line voltage, or write select line voltage) to a predetermined voltage level for operating individual memory cells 103 in the memory array 102.

In some embodiments, each memory cell 103 is embodied as a Resistive Random Access Memory (RRAM) cell. However, it should be understood that the memory cell 103 can be implemented as any of various other non-volatile memory cells, while remaining within the scope of the present disclosure. For example, memory cell 103 may include a magnetoresistive random access memory (MRAM) cell, a phase-change random access memory (PCRAM) cell, an efuse memory cell, an anti-fuse memory cell, etc. In another example, the memory cell 103 can be an OTP memory cell, configured to maintain a state (e.g., bit value) once programmed or written.

In the example of being implemented as an RRAM cell, the memory cell 103 may include a resistor and a transistor coupled to each other in series. The memory cell 103 can be operatively coupled a corresponding set of BL, WL, and SL. The resistor may be formed as a multi-layer stack that includes a top electrode (TE), a capping layer, a variable resistance dielectric (VRD) layer, and a bottom electrode. In some embodiments, the VRD layer may be formed from at least one of the transition metal oxide materials such as, TiOx, NiOx, HfOx, NbOx, CoOx, FeOx, CuOx, VOx, TaOx, WOx, CrOx, and combinations thereof. In some embodiments, the VRD layer may include a high-k dielectric layer. The VRD layer can switch between a high resistance state (HRS) and a low resistance state (LRS), which can correspond to logic 0 and logic 1 of the data bit stored (or programmed) in the memory cell 103.

In general, the TE of the resistor can be coupled to the corresponding BL, the BE of the resistor can be coupled to a first source/drain terminal of the transistor, a gate terminal of the transistor is coupled to the corresponding WL, and a second source/drain terminal of the transistors is coupled to the corresponding SL. To operate the memory cell 103 (which is implemented as an RRAM cell), the transistor is activated (i.e., turned on) by an assertion signal through the WL, and then a voltage with a polarity (e.g., BL is provided with a positive voltage and SL is ground) is applied across the memory cell 103. As such, the higher voltage at BL (and TE) pulls negatively charged oxygen ions from the VRD layer to the capping layer and thus leaves oxygen vacancies within the VRD layer, which allows electron(s) that are present in the BE to travel (hop) from the BE through the VRD and capping layers, and ultimately to the TE. Consequently, a conduction path through the VRD layer is “formed.” Before such a conduction path is formed, the resistor may remain at the HRS. In some embodiments, upon formation of the conduction path, the resistor transitions from the HRS to the LRS, and a relatively higher magnitude of current flows between the BL and the SL.

The row control circuit 104 is a hardware component that can receive a row address of the memory array 102 and assert one or more conductive structures (e.g., a WL) at that row address. The column control circuit 106 is a hardware component that can receive a column address of the memory array 102 and assert one or more conductive structures (e.g., a BL, a SL, and/or a CG) at that column address. The I/O circuit 108 is a hardware component that can access (e.g., read, program) each of the memory cells 103 asserted through the row control circuit 104 (or row decoder) and column control circuit 106 (or column decoder).

In various embodiments of the present disclosure, the voltage control circuit 110 is a hardware component that can provide a number of suitable voltages to access or otherwise operate the memory array through the row control circuit 104, column control circuit 106, and I/O circuit 108, respectively. The voltage control circuit 110 can operate with the row control circuit 104 and the column control circuit 106 to access the memory cells 103 of the memory array 102 for desired read and/or write operations. The voltage control circuit 110 can be configured to manage and regulate the voltage levels supplied to various parts of the circuit 100. The voltage control circuit 110 can include components such as voltage regulators, switches, and control logic that can ensure stable and appropriate voltage levels are maintained during different operational modes. For example, the voltage control circuit 110 can interact with the WLs, BLs, and CGs (e.g., control gate lines) to manage the voltage supplied to selected and/or unselected memory cells 103. In some cases, the level shifter (e.g., WL, BL, or CG level shifter) can be a part of the voltage control circuit 110, to manage the voltage level for the one or more access lines.

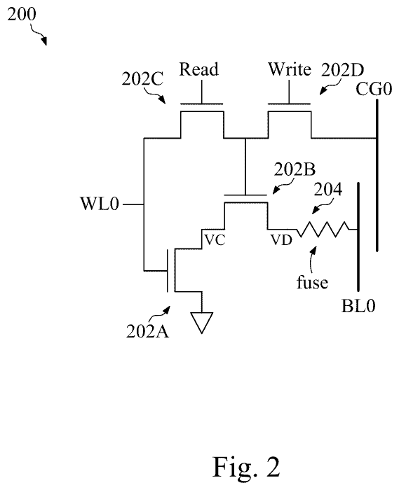

FIG. 2 illustrates an example schematic diagram of a memory cell 200 (e.g., an eFuse cell) in the memory array of FIG. 1, in accordance with some embodiments. As a non-limiting example, the memory cell 200 or components of the memory cell 200 (e.g., transistors 202A-D and resistive element 204) can be a part of the memory array 102, although the memory cell 200 can be implemented as a part of other memory devices or circuits, not limited to memory circuit 100. The memory cell 200 can be composed of hardware components. The memory cell 200 can be one of the memory cells 103, such as described in conjunction with at least FIG. 1. The memory cell 200 can include more or less non-limiting components, elements, or features.

The memory cell 200 can include at least transistors 202A-D (e.g., sometimes referred to as transistor(s) 202), at least one resistive element 204, at least one WL, at least one BL, at least one CG (e.g., control gate line), at least one read select line, at least one write select line, etc. The transistors 202 can include an access transistor 202A, a control gate transistor 202B, a read select transistor 202C, and a write select transistor 202D. The example naming or labeling of the transistors 202 may be provided for illustrative purposes and is not intended to be limiting herein. Each transistor 202 can include respective source/drain (S/D) terminals and a gate terminal. The S/D terminals may be referred to as emitter and collector of the transistor 202. The transistors 202 can be metal-oxide-semiconductor field-effect transistors (MOSFETs).

The transistors 202 can be n-type (e.g., NMOS) transistors (e.g., asserted when a predefined voltage is applied and deasserted when not applying the predefined voltage). The transistors 202 can be p-type (e.g., PMOS) or other types of transistors, not limited to the n-type transistors. In this case, the transistors 202 can have the same conductive type. In some other cases, one or more transistors 202 may include a different conductive type from the other transistors 202.

The transistors 202 can be formed in one or more respective portions (e.g., first portions) of the memory cell 200, or other memory cells 103, along the main surface of a semiconductor substrate (not shown). For example, the memory cell 200 can be fabricated, at least in part, by forming the access transistor 202A, control gate transistor 202B, read select transistor 202C, and write select transistor 202D on the main surface of the semiconductor substrate. The transistors 202 can be formed on or arranged. The main surface can refer to the top layer of the substrate. The main surface can include at least the fabricated transistors 202 or other microelectronic circuits of the memory cell 200. The semiconductor substrate can be composed of silicon, gallium arsenide (GaAs), silicon carbide (SiC), sapphire, or other suitable materials.

The resistive element 204 can be a part of each memory cell 200. The resistive element 204 can be a hardware component, e.g., a non-volatile programmable component, configured to undergo a permanent electrical change when subjected to a programming operation. The resistive element 204 can be formed in one or more respective portions (e.g., second portions) of the memory cells 103 in one or more of a plurality of metallization layers (not shown) disposed over the major surface. The second portion of each of the memory cells 103 can include the respective resistive element 204. The metallization layers can refer to conductive layers in the circuit 100 that form interconnections between the transistors 202, memory cells 103, and other components. The metallization layers can be utilized for routing electrical signals and power across the circuit 100. For example, the metallization layers can include metal traces separated by insulating dielectric layers (e.g., silicon dioxide or low-k materials). The metallization layers can be composed of any suitable materials such as aluminum, copper, tungsten, etc.

The resistive element 204 can store data which may not be altered after programming. The resistive element 204 can take different forms such as an anti-fuse, which starts as a high-resistance material and transitions to a low-resistance state when a relatively high voltage is applied. In some implementations, the resistive element 204 can be a fuse-based element, which begin as a conductive link (e.g., metal or polysilicon) and are broken through a relatively high current or laser operation, for example. The resistive element 204 can be composed of any suitable material, such as silicon oxide or silicon nitride. Different types of resistive elements can be utilized based on the configuration of the memory cell 200.

Each respective type of line (e.g., WL, BL, CG, read select line, or write select line) can be one of a plurality of lines in the memory array 102 of the circuit 100. For example, the circuit 100 can include a plurality of memory cells 103, 200 in the memory array 102, a plurality of WLs, a plurality of CGs; a plurality of BLs, a plurality of read select lines, and/or a plurality of write select lines, among others. Each memory cell 103, 200 can be electrically connected/coupled to one or more corresponding lines for selecting (or unselecting) the memory cell 103, 200 to read or write/program. The lines (e.g., WL, BL, CG, read select line, and/or write select line) can be formed in one or more of the metallization layers disposed over the major surface.

The different lines can extend from, be connected to, or be a part of one or more components of the circuit 100, such as at least one of the row control circuit 104, column control circuit 106, I/O circuit 108, or voltage control circuit 110. For example, the WL can extend from or be electrically connected to the row control circuit 104, configured to select and activate specific rows (e.g., transistors in the specific rows) of memory cells 103 within the memory array 102. The BL can extend from the column control circuit 106, which can be configured to read or write data by transferring charge to or from the selected memory cell in the activated row. The CG can be connected to the column control circuit 106, the voltage control circuit 110, or other components of the circuit 100, for instance, to manage and regulate the voltage levels supplied to the control gates of the memory cells 103 (e.g., the gate terminal of the control gate transistor 202B during a write/program mode or operation). The different lines can be controlled by other components within the circuit 100. The read select line and/or the write select line may be connected to the I/O circuit 108 such as to manage the mode for the memory cell 200, e.g., switch between read mode and write mode by applying or ceasing voltage to the read select or write select transistors 202C-D. In some arrangements, the different lines can be connected to or controlled by other circuits or devices. In some implementations, the voltage control circuit 110 or other components of the circuit 100 can supply the desired current or voltage to the memory cells 103 via different lines.

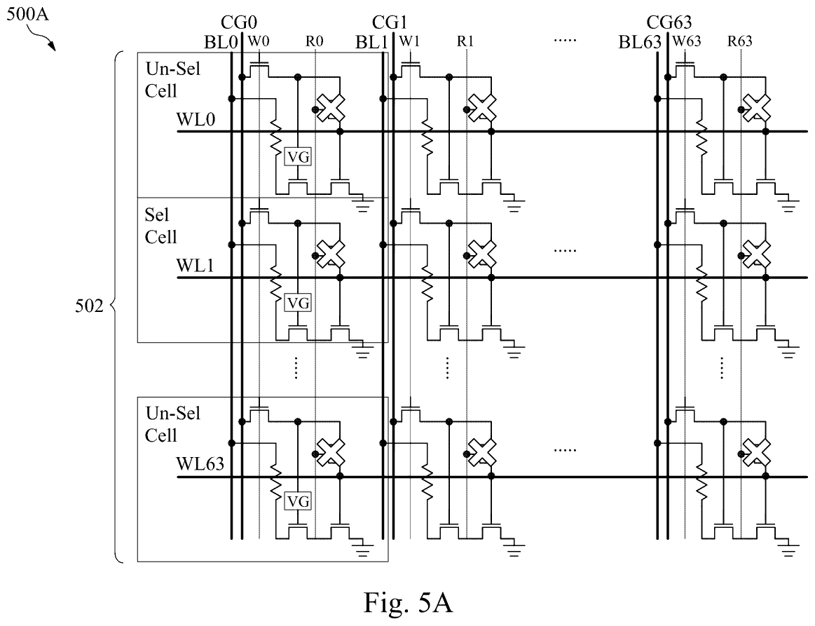

In some arrangements, the WLs of the circuit 100 can extend in a first direction, with the CGs, the BLs, the read select lines, and the write select lines extending a second direction perpendicular to the first direction. For example, the first direction may be a horizontal direction and the second direction may be a vertical direction in the memory array 102. By extending in the respective direction, a correspond one of the BLs, write select lines, and read select lines can be shared across a column of memory cells 103 and a corresponding one of the WLs can be shared across a row of memory cells 103, such as described in conjunction with at least FIGS. 5A-B. The lines may be arranged in other non-limiting directions based on the configuration of the memory array 102.

The interconnects or arrangements between components of the memory cell 200 can be shown in at least FIG. 2. As shown, for example, the access transistor 202A can include a first S/D terminal (electrically) connected to a ground (e.g., ground voltage), a second S/D terminal connected to a first S/D terminal of the control gate transistor 202B, and a gate terminal connected to a corresponding WL and a first S/D terminal of the read select transistor 202C. The control gate transistor 202B can include a second S/D terminal connected to the resistive element 204 and a gate terminal connected to a second S/D terminal of the read select transistor 202C and a first S/D terminal of the write select transistor 202D. The access transistor 202A, the control gate transistor 202B, and the resistive element 204 can be connected in series between the ground and a corresponding BL. The control gate transistor 202B can be interposed between the access transistor 202A and the resistive element 204. The control gate transistor 202B can be electrically connected to the BL via the resistive element 204.

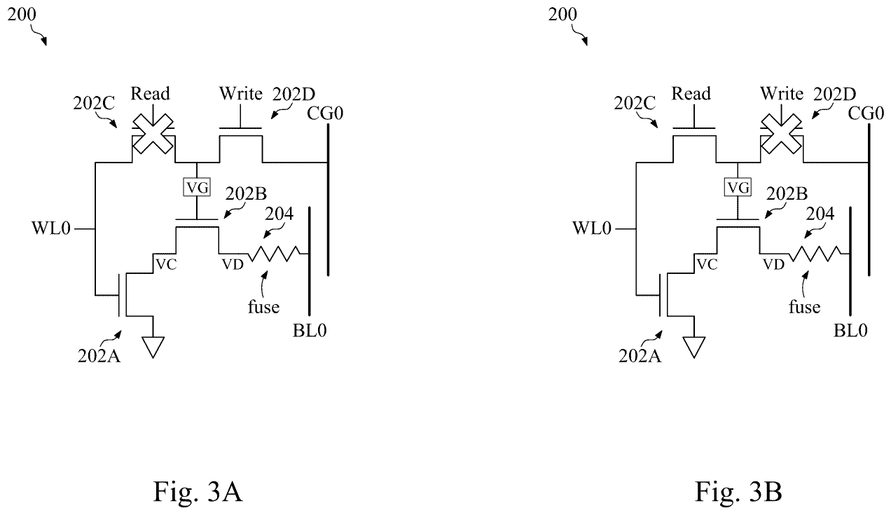

The read select transistor 202C can include the first S/D terminal connected to the WL and the gate terminal of the access transistor 202A, a second S/D terminal connected to the gate terminal of the control gate transistor 202B and the first S/D terminal of the write select transistor 202D, and a gate terminal connected to the read select line. The write select transistor 202D can include the first S/D terminal connected to the gate terminal of the control gate transistor 202B and the second S/D terminal of the read select transistor 202C, a second S/D terminal connected to a corresponding CG, and a gate terminal connected to the write select line. Examples for operating the transistors 202 of the memory cell 200 can be described in conjunction with at least FIGS. 3A-B.

FIGS. 3A-B illustrate example schematic diagrams of the memory cell 200 (e.g., eFuse cell) of FIG. 2 during operation, in accordance with some embodiments. FIG. 3A can illustrate the memory cell 200 during an example write/program operation. FIG. 3B can illustrate the memory cell 200 during an example read operation. FIGS. 3A-B can include the memory cell 200 and components of the memory cell 200 described in conjunction with at least FIG. 2.

For purposes of providing examples, the memory cell 200 can be a selected memory cell for the read and/or write operation. For the selected memory cell, the WL, BL, and CG can carry respective predefined currents or be set to respective predefined voltages. The respective voltages can be applied to one or more transistors 202 via the WL, BL, and CG. As a non-limiting example, the WL can be set to a first voltage level, the BL can be set to a second voltage level, and the CG can be set to a third voltage level for the selected memory cell. For instance, the first voltage can be applied to the access transistor 202A, thereby allowing current flow through the access transistor 202A for the selected cell. The voltage levels can be predetermined according to the configuration of the components of the circuit 100. The applied voltage levels can be associated with current levels from the respective lines. It should be noted that setting a respective line to a predetermined voltage can be referred to as asserting the line and setting the respective line to a relatively low voltage or no voltage can be referred to as deasserting the line.

During the write mode or operation, the read select transistor 202C can be deasserted by the read select line (e.g., not applying the voltage or reducing the voltage below a predefined threshold at the gate terminal of the read select transistor 202C). Deasserting the read select transistor 202C can disconnect the WL from the gate terminal of the control gate transistor 202B. Deasserting a transistor 202 can refer to turning off or deactivating the transistor, thereby preventing the flow of current between the S/D terminals. The write select transistor 202D can be asserted by applying a predefined voltage at the gate terminal via the write select line. Asserting a transistor 202 can refer to turning on or activating the transistor, thereby allowing the flow of current between the S/D terminals.

Deasserting the read select transistor 202C and asserting the write select transistor 202D can cause the voltage present at the CG (e.g., control gate line) to be substantially equal to the gate voltage (VG) present at the gate terminal of the control gate transistor 202B. Applying the gate voltage equal to CG can allow current to flow from the BL through the resistive element 204 (e.g., a fuse), the control gate transistor 202B, and the access transistor 202A, to ground. For instance, the voltage of the BL can be set to a relatively high voltage level (e.g., asserted) to program the memory cell 200 by blowing the resistive element 204, creating a (permanent) change in resistance that represents the stored data.

During the read mode or operation, the read select transistor 202C can be asserted and the write select transistor 202D can be deasserted. Deasserting the write select transistor 202D can disconnect the CG from the gate terminal of the control gate transistor 202B. Subsequently, the voltages present on the gate terminal of the control gate transistor 202B (e.g., VG) and the WL can be substantially equal to each other. In such cases, the access transistor 202A and the control gate transistor 202B can be asserted to allow current flow from the BL to the ground, or vice versa. The voltage drop across the resistive element 204 can be sensed to determine the stored data for the read operation. If the resistive element 204 has been blown, the resistance can be relatively high, resulting in a relatively lower current flow and a relatively higher voltage drop, indicating a programmed state (e.g., logic ‘1’). If the fuse has not been blown, the resistance can be relatively low, resulting in a relatively higher current flow and a relatively lower voltage drop, indicating an unprogrammed state (e.g., logic ‘0’).

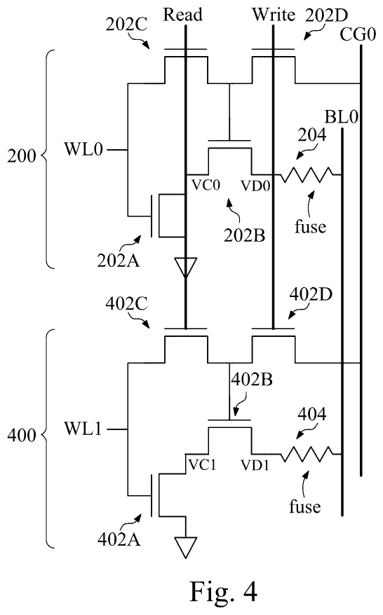

For unselected memory cells, at least one of the WL and/or BL may not be set to the respective predefined voltage (e.g., deasserted). By implementing the switches (e.g., read select transistor 202C and the write select transistor 202D) such as in a 2T configuration, leakage can be prevented or minimized for unselected memory cells. For example, in certain circuits with 2T configuration (without the switches), a gate terminal of a control gate transistor may be connected directly to a corresponding CG. With the corresponding CG and a corresponding BL shared across a column of memory cells, if one memory cell of the 2T configuration is selected, the control gate transistors of other memory cells in the column may be asserted, resulting in a half selected state where there may be a leakage path from the corresponding BL to the ground via unselected (or half selected) memory cells. Hence, with the implementation of the switches (e.g., read select transistor 202C and the write select transistor 202D), the control gate transistors for unselected memory cells may be deasserted, for instance, during the read mode. The utilization of the read select transistor 202C and the write select transistor 202D for minimizing or preventing the leakage can be described in conjunction with at least one of but not limited to FIGS. 4-5B.

FIG. 4 illustrates an example schematic diagram of two eFuse cells (e.g., memory cells 200, 400) in the memory array 102 of FIG. 1, in accordance with some embodiments. FIGS. 5A-5B illustrate example schematic diagrams 500A-B of the memory array including eFuse cells (e.g., memory cell 200) of at least FIG. 2 during operation, in accordance with some embodiments. FIG. 4 can include a memory cell 400 including similar components or configuration as the memory cell 200. For instance, the memory cell 400 can include transistors 402A-D (e.g., sometimes referred to as transistor(s) 402) and a resistive element 404 similar to the transistors 202 and the resistive element 204 of the memory cell 200. The memory cells 200, 400 can be in the same column within the memory array 102.

As shown in FIG. 4, the memory cells 200, 400 within the column of memory cells 103 can share a corresponding CG, BL, read select line, and write select line. Each row of memory cells 103 can share a corresponding WL. In scenarios when one of the memory cells 200, 400 is selected, the BL and the CG can be asserted. The WL associated with the selected memory cell can be asserted and the other WL associated with the unselected memory cell may not be set to the predefined voltage (or deasserted).

During the write operation, the write select transistors 202D, 402D can be asserted and the read select transistors 202C, 402C can be deasserted, thereby allowing the selected memory cell to be programmed (if not already programmed). The WL of the unselected memory cell may not be set to the predefined voltage (e.g., 0V), thereby deasserting the corresponding access transistor 202A or 402A. During the read operation, the write select transistors 202D, 402D can be deasserted and the read select transistors 202C, 402C can be asserted, thereby disconnecting the CG from the gate terminal of the control gate transistors 202B, 402B. The WL associated with the unselected memory cell may not be set to the predefined voltage. By disconnecting the CG from the gate terminal of the control gate transistor 202B or 402B associated with the unselected memory cell, leakage can be minimized or avoided during read operation of another (selected) memory cell. For instance, both the access transistor 202A or 402A and control gate transistor 202B or 402B of the unselected memory cell can be deasserted, blocking current flow, e.g., instead of being in the half selected state for 2T configuration without switches.

FIGS. 5A-B illustrate an example arrangement of the WLs, BLs, CGs, write select lines, and read select lines connected to different memory cells 502 in a 64×64 memory array. The memory array of FIGS. 5A-B can be a different size, not limited to 64×64 memory array. Each of the memory cells 502 can include components or configuration similar to at least one of memory cells 200, 400 as described in conjunction with FIGS. 2 and 4. The schematic diagram 500A can illustrate the memory cells 502 during the write or program mode. During the program mode, the gate voltage (VG) of the gate transistors in the memory cells 502 can be controlled by or set to the voltage of the CG, which can be configured at around a half (or a fraction) of the voltage applied on the BL. As such, the unselected memory cells may see less BL stress, such as when the BL is asserted (e.g., set to a relatively high voltage) for programming the selected memory cell.

The schematic diagram 500B can illustrate the memory cells 502 during the read mode. In the read mode, the VG of the control gate transistors can be controlled by the WL, e.g., depend on the voltage of the WL. For unselected memory cells, the control gate transistors can be deasserted by deasserting the WL (e.g., set to a low state such as 0V or below the predefined voltage). For the selected memory cell, the control gate transistor can be asserted by applying the voltage of the WL to the gate terminal of the control gate transistor, e.g., VG can be substantially equal to the WL voltage. In such cases, leakage can be mitigated for unselected memory cells during the read mode by deasserting (or maintain the deassertion of) the access transistors and control gate transistors in the unselected memory cells.

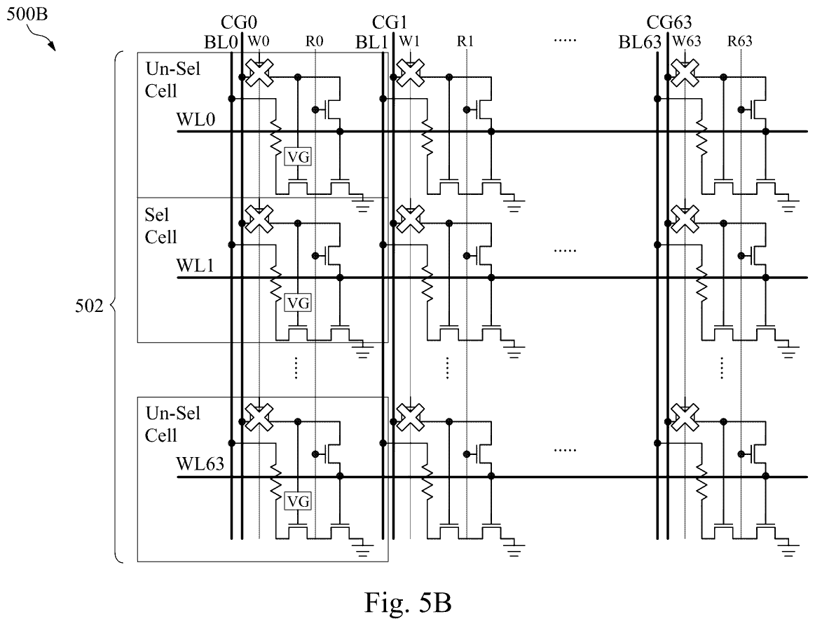

FIG. 6 illustrates an example schematic diagram of an eFuse cell (e.g., memory cell 600) with p-channel metal-oxide-semiconductor (PMOS) switches in the memory array of FIG. 1, in accordance with some embodiments. The memory cell 600 can be one of the memory cells 103 in the memory array 102. The memory cell 600 can include one or more components or arrangements similar to or different from at least one of the memory cells 200, 400, or 502 as described in conjunction with at least one of but not limited to FIGS. 2-5B. The memory cell 600 can be implemented in the memory array 102 additionally to or alternatively from the memory cell 200.

The memory cell 600 can include transistors 602A-D (e.g., sometimes referred to as transistor(s) 602) and a resistive element 604. The resistive element 604 can be similar to or different from at least the resistive element 204 for OTP programming, for example. The transistors 602A-D can include an access transistor 602A, a control gate transistor 602B, a read select transistor 602C, and a write select transistor 602D. The access transistor 602A and the control gate transistor 602B can be similar to transistors 202A-B of the memory cell 200. In this case, the read select transistor 602C and the write select transistor 602D can be implemented using PMOS transistors. With PMOS transistors, each of the read and write select transistors 602C-D can be asserted by applying a respective predefined voltage at the gate terminal via the read and write select lines, respectively, and deasserted by terminating or not applying the predefined voltage at the gate terminal. The operation of the memory cell 600 during the read or write modes can be similar to or described in conjunction with at least one of FIGS. 2-5B.

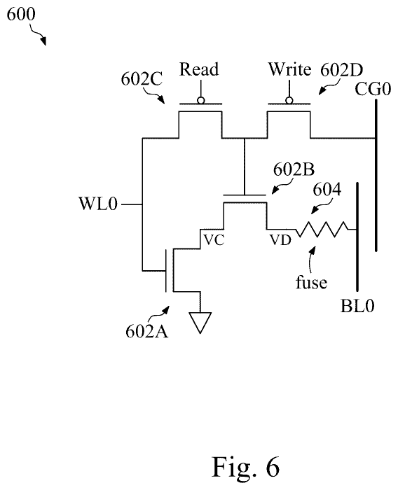

FIG. 7 illustrates an example schematic diagram of an eFuse cell (e.g., memory cell 700) with mix switches in the memory array of FIG. 1, in accordance with some embodiments. The memory cell 700 can be one of the memory cells 103 in the memory array 102. The memory cell 700 can include one or more components or arrangements similar to or different from at least one of the memory cells 200, 400, 502, or 600 as described in conjunction with at least one of but not limited to FIGS. 2-6. The memory cell 700 can be implemented in the memory array 102 additionally to or alternatively from the memory cell 200.

The memory cell 700 can include transistors 702A-D (e.g., sometimes referred to as transistor(s) 702) and a resistive element 704. The resistive element 704 can be similar to or different from at least the resistive element 204. The transistors 702A-D can be similar to the transistors 202A-D, for example, including an access transistor 702A, a control gate transistor 702B, a read select transistor 702C, and a write select transistor 702D. In some configurations, the read select transistor 702C and the write select transistor 702D can be different types of transistors (e.g., mix switches). For example, the read select transistor 702C can be a PMOS transistor and the write select transistor 702D can be an NMOS transistor, or vice versa. With the different switches, a mode select line (e.g., labeled as ‘RW’) can be connected to the gate terminals of the read and write select transistors 702C-D to assert one of the transistors 702C-D and deassert the other one of the transistors 702C-D.

Using the read select transistor 702C as a PMOS transistor and the write select transistor 702D as an NMOS transistor for example, the memory cell 700 can operate in a write mode by applying a logic ‘1’ or setting a predefined voltage to the mode select line. By applying the predefined voltage at the gate terminals of the read and write select transistors 702C-D, the read select transistor 702C can be deasserted and the write select transistor 702D can be asserted. By terminating or blocking the voltage to the gate terminals of the transistors 702C-D (or applying logic ‘0’), the read select transistor 702C can be asserted and the write select transistor 702D can be deasserted.

In the case of the read select transistor 702C being an NMOS transistor and the write select transistor 702D being a PMOS transistor, for example, applying the predefined voltage at the gate terminals can assert and deassert the read and write select transistors 702C-D, respectively, and not applying the predefined voltage at the gate terminals can deassert and assert the read and write select transistors 702C-D, respectively. The operation of the memory cell 700 during the read or write modes can be similar to or described in conjunction with at least one of FIGS. 2-6.

In some implementations, at least one inverter can be utilized or be coupled to the gate terminal of at least one of the read select transistor 202C or write select transistor 202D being the same type. For example, to operate transistors 202C-D (e.g., NMOS transistors) similar to transistors 702C-D (e.g., transistor 702C being PMOS transistor and transistor 702D being NMOS transistor), an inverter can be implemented, added, or otherwise connected to the gate terminal of the read select transistor 202C, such that a high signal can be inverted to a low signal and vice versa. In some other configurations, the inverter can be implemented to the gate terminal of the write select transistor 202D. Other types of circuits or components can be utilized or implemented to achieve the desired features or functionalities discussed herein.

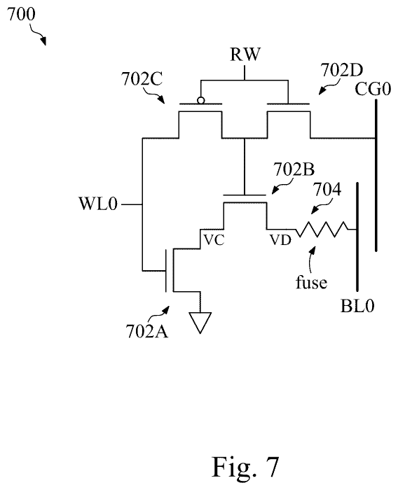

FIG. 8 illustrates an example schematic diagram of eFuse cells (e.g., memory cells 800) coupled to switches 806A-B in the memory array of FIG. 1, in accordance with some embodiments. The memory cells 800 can be part of the memory array 102 in the circuit 100 of FIG. 1. Four memory cells 800 can be shown in FIG. 8 as an illustrative example, although more or less number of memory cells 800 can be included as part of the circuit 100. One or more of the memory cells 800 can include one or more components or features similar to at least one of the memory cell 103, 200, 400, 502, 600, or 700, among others. Each of the memory cells 800 can include two transistors, e.g., a respective access transistor 802A, 802C, 802E, 802G and a respective control gate transistor 802B, 802D, 802F, 802H, and a corresponding one of resistive elements 804A-D (e.g., sometimes referred to as resistive element(s) 804).

The resistive element 804 can operate similar to the resistive element 204, for example. The transistors 802A-H can sometimes be referred to as transistor(s) 802. Individual access and control gate transistors 802 can operate similar to the access transistor 202A and the gate transistor 202B, respective. As shown, a first memory cell can include transistors 802A-B and resistive element 804A, a second memory cell can include transistors 802C-D and resistive element 804B, a third memory cell can include transistors 802E-F and resistive element 804C, and a fourth memory cell can include transistors 802G-H and resistive element 804D.

To minimize leakage such as at least during the read mode, one or more switches 806 can be implemented to manage the CG voltage (e.g., manage the current flow via the CG). The switch 806 can include one or more logics suitable for controlling the CG. Each switch 806 can be operated or controlled using a control signal from at least the mode select line (RW), e.g., according to at least the RW to implement features or functionalities similar to at least the memory cell 200. The switch 806 can control the CG according to the RW and the WL. Individual switches 806 can be implemented in respective rows of the memory array 102, whereby controlling the CG can assert or deassert one or more respective control gate transistors 802B, 802D, 802F, 802H. The CG can extend in a first direction parallel to the WL and perpendicular to a second direction of the BL.

For example, the switch 806 can receive signals from the WL and the RW. The signal from the WL can indicate whether at least one of the switches 806 in the corresponding row of switches 806 is selected. The switch 806 may not assert the CG when there is no signals from the WL or the WL is deasserted. When the WL is asserted, the switch 806 can determine whether to assert the CG by setting a predefined voltage for the CG based on or according to the RW (e.g., whether read mode or program mode). A value or a state of the RW can be indicative of the read mode or program mode, e.g., such as a high state for read mode and a low state for program mode, or vice versa. The switch 806 may deassert the CG during the read mode.

The switch 806 may assert the CG to assert the gate terminals of the one or more control gate transistors 802B, 802D, 802F, 802H during the program mode. In such cases, the corresponding one or more control gate transistors 802B, 802D, 802F, 802H can be deasserted during the read mode and asserted during the program mode. By deasserting the control gate transistors 802B, 802D, 802F, 802H for unselected memory cells and/or during the read mode (instead of having the memory cells be in a half-selected state), potential leakage from the BL to the ground can be minimize or prevented.

In some configurations, the one or more switches 806 can be implemented additionally or alternatively to the read and write select transistors 202C-D, such as described in conjunction to at least FIG. 2. In some configurations, the WL level shifter and the CG level shifter (not shown) for controlling the CG can be a part of or included in the row control circuit 104. The switches 806 may be included as part of the row control circuit 104, for example.

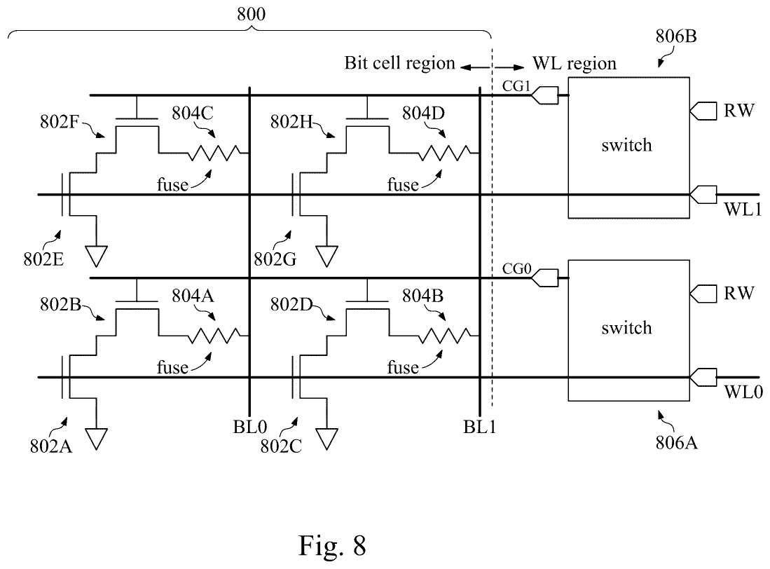

FIG. 9 illustrates an example schematic diagram of an eFuse cell (e.g., memory cell 900) with three transistors 902A-C in the memory array of FIG. 1, in accordance with some embodiments. The memory cell 900 can be one of the memory cells 103 of the memory array 102. The memory cell 900 can include one or more components or features similar to (or different from) at least one of memory cell 103, 200, 400, 502, 600, 700, or 800 among others. The memory cell 900 can include three transistors 902A-C (e.g., sometimes referred to as transistor(s) 902) and a resistive element 904. The resistive element 904 can be similar to (or different from) the resistive element 204 for OTP operation.

The three transistors 902 can include two access transistors 902A-B and a control gate transistor 902C. The two access transistors 902A-B can be connected in series with the control gate transistor 902C and the resistive element 904. The gate terminals of the two access transistors 902A-B can be connected to the WL. The access transistors 902A-B can be controlled according to the signals from the WL. Each of the two access transistors 902A-B can include features or functionalities similar to the access transistor 202A as described in conjunction with at least FIG. 2, for example. The access transistors 902A-B can perform similar operations to each other.

The control gate transistor 902C can include features or functionalities similar to the control gate transistor 202B as described in conjunction with at least FIG. 2, for example. Although shown as NMOS transistors, the transistors 902 may be other types of transistors, such as PMOS transistors or a combination of NMOS and PMOS transistors. In some implementations, by implementing two access transistors, e.g., 902A-B, the leakage from the BL to the ground can be minimize at least during the read operation. For example, if the memory cell 900 is an unselected memory cell and the control gate transistor 902C is asserted via the CG voltage, the two access transistors 902A-C can remain deasserted to prevent the current flow from the BL to the ground, thereby minimizing or avoiding the potential leakage. In some configurations, the memory cell 900 can include more than two access transistors 902A-B.

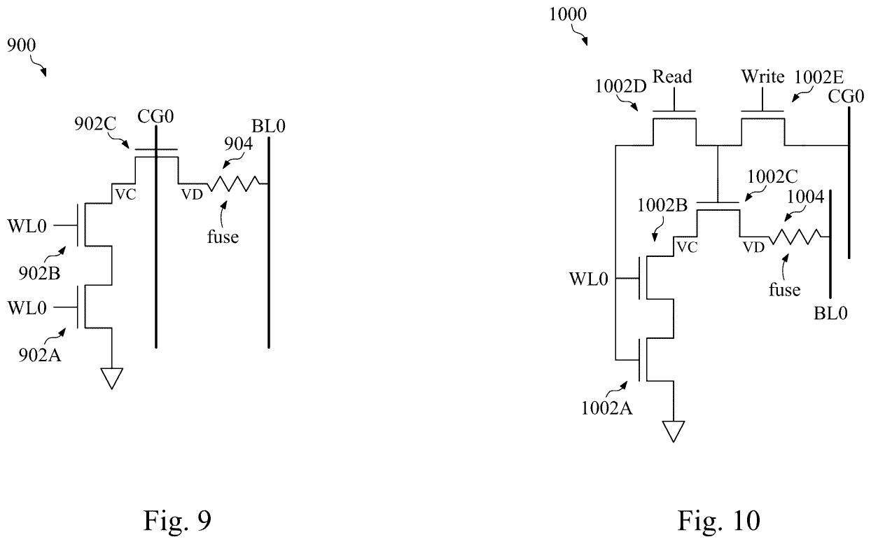

FIG. 10 illustrates an example schematic diagram of an eFuse cell (e.g., 1000) in the memory array of FIG. 1 including multiple access transistors and switches, in accordance with some embodiments. The memory cell 1000 can be one of the memory cells 103 of the memory array 102. The memory cell 1000 can include one or more components or features similar to (or different from) at least one of memory cell 103, 200, 400, 502, 600, 700, or 800 among others. As shown, the memory cell 1000 can include, but is not limited to, transistors 1002A-E (e.g., sometimes referred to as transistor(s) 1002) and a resistive element 1004. The resistive element 1004 can be similar to (or different from) the resistive element 204 for OTP operation.

The transistors 1002 can include but is not limited to at least two access transistors 1002A-B, at least one control gate transistor 1002C, at least one read select transistor 1002, and at least one write select transistor 1002E. The read select transistor 1002 and the write select transistor 1002E can be switches operating according to the operation mode (e.g., read or program mode) of the memory cell 1000. Although shown as NMOS transistors, the transistors 902 may be other types of transistors, such as PMOS transistors or a combination of NMOS and PMOS transistors.

The memory cell 1000 may be configured similar to a combination of the memory cells 200, 900. For example, the transistors 1002B-E can be interconnected and operate similar to transistors 202A-D, respectively. In further examples, another access transistor (e.g., 1002A or 1002B) can be added, such as similar to having the transistors 902A-B. The operation of the memory cell 1000 can be similar to the operation of the memory cell 200.

For example, the read select transistor 1002D can be asserted and the write select transistor 1002E can be deasserted during the read mode, and the read select transistor 1002D can be deasserted and the write select transistor 1002E can be asserted during the program mode. If the memory cell 1000 is selected (or another memory cell associated in the same row as the memory cell 1000), the WL can be asserted, thereby asserting at least the access transistors 1002A-B (and the control gate transistor 1002C during the read mode). If the memory cell 1000 or the row associated with the memory cell 1000 is unselected, the WL can be deasserted, thereby deasserting the access transistors 1002A-B (and the control gate transistor 1002C during the read mode). The switches (e.g., read and write select transistors 1002D-E) and the multiple access transistors 1002A-B can be utilized minimize or prevent the leakage from the BL to the ground at least during the read mode.

It should be noted that the configurations or arrangements of components of the various memory cells discussed herein can be mixed, combined, or otherwise integrated with each other, for instance, as part of a memory cell configuration. In some implementations, the one or more different arrangements of the memory cells discussed herein may be implemented in the same memory array or different memory arrays of one or more memory devices/circuits.

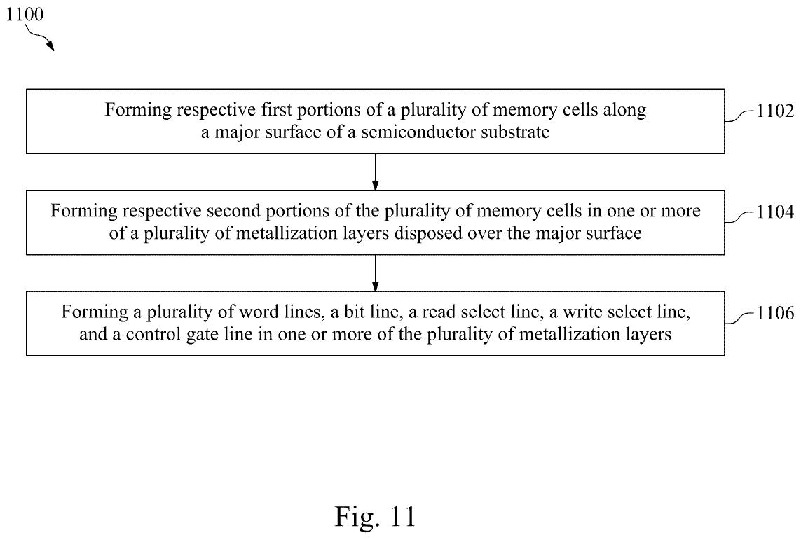

FIG. 11 illustrates a flow chart of an example method 1100 for forming a memory device (e.g., device or circuit 100) including eFuse bit-cells (e.g., at least one of memory cells 103, 200, 400, 502, 600, 700, 900, or 1000) in stacking structure of FIGS. 1-10 to enhance leakage tolerance, in accordance with some embodiments. The operations of the method 1100 may be performed by the components described hereinabove, e.g., at least one of but not limited to FIGS. 1-10, and thus, some of the reference numerals used above may be re-used the following discussion of the method 1100. Further, it is understood that the method 1100 has been simplified, and thus, additional operations may be provided before, during, and after the method 1100 of FIG. 11, and that some other operations may only be briefly described herein. It should also be noted that alternative operations may be provided as part of the method 1100 of FIG. 11.

The method 1100 starts with operation 1102 of forming respective first portions of a plurality of memory cells (e.g., 103, 200, etc.) along a major surface of a semiconductor substrate. The first portion of each of the memory cells can include/comprise an access transistor (e.g., at least one of 202A, 402A, etc.), a control gate transistor (e.g., at least one of 202B, 402B, etc.), a read select transistor (e.g., at least one of 202C, 402C, etc.), and a write select transistor (e.g., at least one of 202D, 402D, etc.). Each of the memory cells can include or correspond to a one-time-programmable (OTP) memory cell. In some configurations, one or more memory cells can include multiple access transistors, not limited to one access transistor.

The method 1100 continues to operation 1104 of forming respective second portions of the memory cells in one or more of a plurality of metallization layers disposed over the major surface. The second portion of each of the memory cells can include a resistive element (e.g., at least one of 204, 404, etc.). The resistive element can include or correspond to a fuse configured to store data. For OTP operation, the resistive element can be blown after programming, thereby creating a (permanent) change in resistance that represents the stored data, for example.

The method 1100 continues to operation 1106 of forming a plurality of word lines, a BL, a read select line, a write select line, and a control gate line in one or more of the metallization layers. The lines can be formed for connection to one or more components of the memory cells within a column. In some implementations, the method 1100 can include forming a plurality of BLs, a plurality of read select lines, a plurality of write select lines, and a plurality of control gate lines (e.g., CGs) in one or more of the metallization layers in the memory device for connection with respective memory cells within the memory array (e.g., having columns and rows of memory cells). For purposes of providing examples, the memory cells can be formed in a column across multiple rows, e.g., as shown in at least FIG. 4.

The method 1100 can include respectively connecting the WLs to gate terminals of the access transistors of the memory cells. The method 1100 can include commonly connecting the BL to respective first source/drain terminals of the resistive elements of the memory cells. The method 1100 can include commonly connecting the read select line to respective gate terminals of the read select transistors of the memory cells. The method 1100 can include commonly connecting the write select line to respective gate terminals of the write select transistors of the memory cells. The method 1100 can include commonly connecting the control gate line to respective one of the source/drain terminals of the write select transistors of the memory cells.

The method 1100 can include respectively connecting the WLs to respective first source/drain terminals of the read select transistors of the memory cells. The method 1100 can include connecting each of the respective second source/drain terminals of the read select transistors to a first source/drain terminal of the write select transistor of a corresponding one of the memory cells. The method 1100 can include connecting the second source/drain terminal of the read select transistor and the first source/drain terminal of the write select transistor of each of the memory cells to a gate terminal of the gate select transistor of the corresponding memory cell.

For each of the memory cells, the access transistor, the control gate transistor, and the resistive element can be connected to one another in series. The method 1100 can include connecting the gate terminal of the access transistor and the gate terminal of the control gate transistor to the first and second source/drain terminals of the read select transistor, respectively. The method 1100 can include connecting the gate terminal of the control gate transistor and a corresponding one of the CGs to the first and second source/drain terminals of the write select transistor, respectively.

In various configurations, the access transistor, the control gate transistor, and the resistive element can be connected between a ground voltage and the BL (or the corresponding one of the BLs of the memory array). In some implementations, when the corresponding memory cell is selected to be programmed (e.g., program mode) through at least asserting a corresponding one of the word lines, the read select transistor can be turned off or deasserted by a corresponding one of the read select lines (e.g., deasserting the read select line or setting relatively low or no voltage at the read select line) and the write select transistor can be turned on or asserted by a corresponding one of the write select lines (e.g., asserting the write select line or setting a predefined voltage at the write select line). Respective voltages present on the gate terminal of the control gate transistor and the CG can be substantially equal to each other, for instance, when asserting the write select transistor and deasserting the read select transistor. The asserted WL can be disconnected from the gate terminal of the gate select transistor subsequent to deasserting the read select transistor.

In some implementations, when the corresponding memory cell is selected to be read through at least asserting a corresponding one of the word lines, the read select transistor can be turned on or asserted by a corresponding one of the read select lines (e.g., asserting the read select line) and the write select transistor is turned off or deasserted by a corresponding one of the write select lines (e.g., deasserting the write select line). Respective voltages present on the gate terminal of the control gate transistor and a corresponding of the WLs can be substantially equal to each other, for instance, when asserting the read select transistor and deasserting the write select transistor. Subsequent to deasserting the write select transistor, the CG can be disconnected from the gate terminal of the gate select transistor.

The WLs can extend in a first direction, with the CGs, the BLs, the read select lines, and the write select lines extending a second direction perpendicular to the first direction. In some other configurations, one or more of the CGs, the read select lines, or the write select lines may extend in the first direction. The lines may extend in other non-limiting directions.

In some configurations, the method 1100 can form the memory device to include a first decoder, a second decoder, and at least one level shifter. The first decoder (e.g., WL decoder) can be configured to receive and decode a first portion of an address signal. The second decoder (e.g., BL decoder) can be configured to receive and decode a second portion of the address signal. The at least one level shifter (e.g., WL, BL, CG level shifter, etc.) can be configured to adjust a voltage in at least one of the WLs, at least one of the BLs, at least one of the CGs, at least one of the write select lines, or at least one of the read select lines, etc. The first decoder can be configured to select one or more of the WLs based on the first portion of the address signal. The second decoder can be configured to select one or more of the BLs based on the second portion of the address signal.

In some configurations, the read select transistor and the write select transistor can have a same conductive type, such as n-type or p-type. In some other configurations, the read select transistor and the write select transistor may have different conductive types, such as a mix of n-type for one of the transistors and p-type for another one of the transistors. In such configurations, the gate terminals of the read and write select transistors can be connected to one select line (e.g., mode select line). For instance, by asserting the mode select line, one of the read or write select transistors can be asserted and the other one of the read or write select transistors can be deasserted. Similarly, by deasserting the mode select line, one of the read or write select transistors can be deasserted and the other one of the read or write select transistors can be asserted. Which of the read or write select transistors to assert when the mode select line is asserted can be based on the configuration of the memory cell.

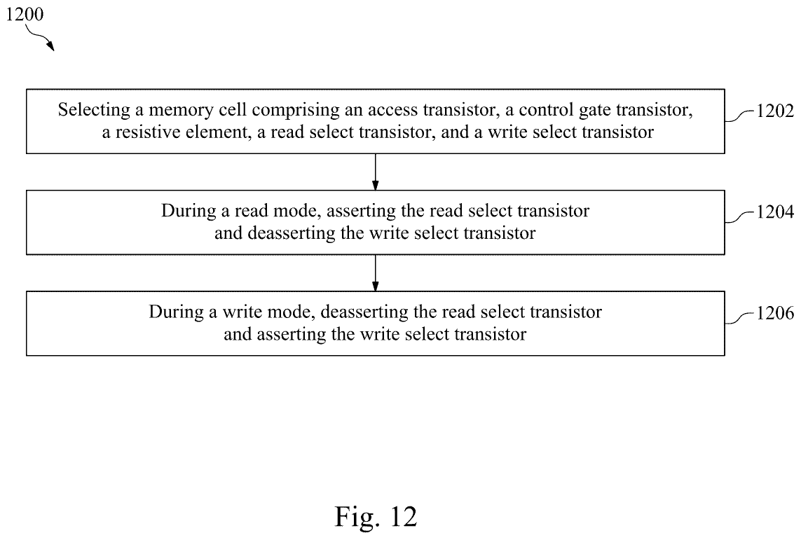

FIG. 12 illustrates a flow chart of an example method 1100 for operating a memory device (e.g., device or circuit 100) including eFuse bit-cells (e.g., at least one of memory cells 103, 200, 400, 502, 600, 700, 900, or 1000) in stacking structure of FIGS. 1-10 to enhance leakage tolerance, in accordance with some embodiments. The operations of the method 1200 may be performed by the components described hereinabove, e.g., at least one of but not limited to FIGS. 1-10, and thus, some of the reference numerals used above may be re-used the following discussion of the method 1200. Further, it is understood that the method 1200 has been simplified, and thus, additional operations may be provided before, during, and after the method 1200 of FIG. 12, and that some other operations may only be briefly described herein. It should also be noted that alternative operations may be provided as part of the method 1200 of FIG. 12.

The method 1200 starts with operation 1202 of selecting a memory cell from a plurality of memory cells (e.g., 103, 200, etc.). The memory cell can be selected to be programmed or read. Each of the memory cells can include an access transistor (e.g., at least one of 202A, 402A, etc.), a control gate transistor (e.g., at least one of 202B, 402B, etc.), a resistive element (e.g., at least one of 204, 404, etc.), a read select transistor (e.g., at least one of 202C, 402C, etc.), and a write select transistor (e.g., at least one of 202D, 402D, etc.) electrically coupled to each other. For example, the access transistor, the control gate transistor, and the resistive element can be connected to one another in series between a ground voltage and a corresponding BL (of a plurality of BLs). A gate terminal of the access transistor and a gate terminal of the control gate transistor can be connected to first and second source/drain terminals of the read select transistor, respectively. The gate terminal of the control gate transistor and a corresponding control gate line can be connected to first and second source/drain terminals of the write select transistor, respectively. The gate terminal of the access transistor and the first source/drain terminal of the read select transistor can be connected to a corresponding WL (of a plurality of WLs).

The method 1200 continued to operation 1204 of asserting the read select transistor and deasserting the write select transistor during a read mode/operation. The read select transistor can be asserted via a read select line, e.g., applying a predefined voltage to the read select line to activate the read select transistor. The write select transistor can be deasserted via a write select line, e.g., not applying voltage to the write select line, thereby deactivating the write select transistor. When the read select transistor is deasserted and the write select transistor is asserted, a first voltage at the corresponding control gate line can be applied at the gate terminal of the control gate transistor. The WL can be disconnected from the gate terminal of the gate select transistor during the write operation.

The method 1200 continued to operation 1206 of deasserting the read select transistor and asserting the write select transistor during a write mode. The read select transistor can be deasserted via the read select line and the write select transistor can be asserted via the write select line. When the read select transistor is asserted and the write select transistor is deasserted, a second voltage at the corresponding WL can be applied at the gate terminal of the control gate transistor. The gate control line can be disconnected from the gate terminal of the gate select transistor during the read operation, thereby minimizing or avoiding leakage during read operation of another (selected) memory cell.

In one aspect of the present disclosure, a memory device is disclosed. The memory device includes a plurality of memory cells, each of the plurality of memory cells comprising an access transistor, a control gate transistor, a resistive element, a read select transistor, and a write select transistor; a plurality of word lines; a plurality of control gate lines; a plurality of bit lines; a plurality of read select lines; and a plurality of write select lines; wherein, for each of the plurality of memory cells, the access transistor, the control gate transistor, and the resistive element are connected to one another in series, a gate terminal of the access transistor and a gate terminal of the control gate transistor are connected to first and second source/drain terminals of the read select transistor, respectively, and the gate terminal of the control gate transistor and a corresponding one of the control gate lines are connected to first and second source/drain terminals of the write select transistor, respectively.

In another aspect of the present disclosure, a memory device is disclosed. The memory device includes a plurality of memory cells, each of the plurality of memory cells comprising an access transistor, a control gate transistor, a resistive element, a read select transistor, and a write select transistor, wherein the plurality of memory cells are respectively coupled to a plurality of word lines, and are commonly coupled to a bit line, a read select line, a write select line, and a control gate line.

In yet another aspect of the present disclosure, a method for operating a memory device is disclosed. The method includes selecting a memory cell from a plurality of memory cells, the memory cell comprising an access transistor, a control gate transistor, a resistive element, a read select transistor, and a write select transistor electrically coupled to each other; during a read mode: asserting the read select transistor via a read select line; and deasserting the write select transistor via a write select line; and during a write mode: deasserting the read select transistor via the read select line; and asserting the write select transistor via the write select line.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of memory cells, each of the plurality of memory cells comprising an access transistor, a control gate transistor, a resistive element, a read select transistor, and a write select transistor;
a plurality of word lines;
a plurality of control gate lines;
a plurality of bit lines;
a plurality of read select lines; and
a plurality of write select lines,
wherein, for each of the plurality of memory cells, the access transistor, the control gate transistor, and the resistive element are connected to one another in series, a gate terminal of the access transistor and a gate terminal of the control gate transistor are connected to first and second source/drain terminals of the read select transistor, respectively, and the gate terminal of the control gate transistor and a corresponding one of the control gate lines are connected to first and second source/drain terminals of the write select transistor, respectively.

2. The memory device of claim 1, wherein each of the plurality of memory cells includes a one-time-programmable memory cell.

3. The memory device of claim 1, wherein the gate terminal of the access transistor is connected to a corresponding one of the word lines.

4. The memory device of claim 1, wherein the access transistor, the control gate transistor, and the resistive element are connected between a ground voltage and a corresponding one of the bit lines.

5. The memory device of claim 1, wherein, when the corresponding memory cell is selected to be programmed through at least asserting a corresponding one of the word lines, the read select transistor is turned off by a corresponding one of the read select lines and the write select transistor is turned on by a corresponding one of the write select lines.

6. The memory device of claim 5, wherein respective voltages present on the gate terminal of the control gate transistor and the control gate line are substantially equal to each other.

7. The memory device of claim 1, wherein, when the corresponding memory cell is selected to be read through at least asserting a corresponding one of the word lines, the read select transistor is turned on by a corresponding one of the read select lines and the write select transistor is turned off by a corresponding one of the write select lines.

8. The memory device of claim 7, wherein respective voltages present on the gate terminal of the control gate transistor and a corresponding of the word lines are substantially equal to each other.

9. The memory device of claim 1, wherein the word lines extend in a first direction, with the control gate lines, the bit lines, the read select lines, and the write select lines extending a second direction perpendicular to the first direction.

10. The memory device of claim 1, further comprising:
a first decoder configured to receive and decode a first portion of an address signal;
a second decoder configured to receive and decode a second portion of the address signal; and
at least one level shifter configured to adjust a voltage in at least one of the word lines, at least one of the bit lines, at least one of the control gate lines, at least one of the write select lines, or at least one of the read select lines,
wherein the first decoder is configured to select one or more of the word lines based on the first portion of the address signal, and the second decoder is configured to select one or more of the bit lines based on the second portion of the address signal.

11. The memory device of claim 1, wherein the read select transistor and the write select transistor have a same conductive type.

12. A memory device, comprising:
a plurality of memory cells, each of the plurality of memory cells comprising an access transistor, a control gate transistor, a resistive element, a read select transistor, and a write select transistor,
wherein the plurality of memory cells are respectively coupled to a plurality of word lines, and are commonly coupled to a bit line, a read select line, a write select line, and a control gate line.

13. The memory device of claim 12, wherein the plurality of memory cells are arranged along a first direction, with the bit line, the read select line, the write select line, and the control gate line extending along the direction, and with the word lines extending along a second direction perpendicular to the first direction.

14. The memory device of claim 12, wherein, when one of the plurality of memory cells is selected to be programmed through at least asserting a corresponding one of the word lines, the read select line is deasserted and the write select line is asserted, causing respective voltages present on a gate terminal of the gate select transistor and on the gate select line to be equal to each other.

15. The memory device of claim 14, wherein the asserted word line is disconnected from the gate terminal of the gate select transistor.

16. The memory device of claim 12, wherein, when one of the plurality of memory cells is selected to be read through at least asserting a corresponding one of the word lines, the read select line is asserted and the write select line is deasserted, causing respective voltages present on a gate terminal of the gate select transistor and on the corresponding word line to be equal to each other.

17. The memory device of claim 16, wherein the control gate line is disconnected from the gate terminal of the gate select transistor.

18. A method for operating a memory device, comprising:
selecting a memory cell from a plurality of memory cells, the memory cell comprising an access transistor, a control gate transistor, a resistive element, a read select transistor, and a write select transistor electrically coupled to each other;
during a read mode:
asserting the read select transistor via a read select line; and
deasserting the write select transistor via a write select line; and
during a write mode:
deasserting the read select transistor via the read select line; and
asserting the write select transistor via the write select line.

19. The method of claim 18, wherein:
the access transistor, the control gate transistor, and the resistive element are connected to one another in series between a ground voltage and a corresponding bit line;
a gate terminal of the access transistor and a gate terminal of the control gate transistor are connected to first and second source/drain terminals of the read select transistor, respectively;
the gate terminal of the control gate transistor and a corresponding control gate line are connected to first and second source/drain terminals of the write select transistor, respectively; and
the gate terminal of the access transistor and the first source/drain terminal of the read select transistor are connected to a corresponding word line.

20. The method of claim 19, wherein:
when the read select transistor is deasserted and the write select transistor is asserted, a first voltage at the corresponding control gate line is applied at the gate terminal of the control gate transistor; and
when the read select transistor is asserted and the write select transistor is deasserted, a second voltage at the corresponding word line is applied at the gate terminal of the control gate transistor.
